(19) United States
(12) Patent Application Publication
(10) Pub. No.: US 2006/0105203 A1
(43) Pub. Date: May 18, 2006

(54) Head disc interface design

(75) Inventors: Lei Li, Pittsburgh, PA (US); Christopher L. Platt, Pittsburgh, PA (US); Yiao-Tee Hsia, Wexford, PA (US)

Correspondence Address: SEAGATE TECHNOLOGY LLC C/O WESTMAN;CHAMPLIN & KELLY, P.A., SUITE 1400 - INTERNATIONAL CENTRE, 900 SECOND AVENUE SOUTH, MINNEAPOLIS, MN, 55402-3319, US

(73) Assignee: Seagate Technology LLC, Scotts Valley, CA (US)

(21) Appl. No.: 10/989,030

(22) Filed: Nov. 15, 2004

(51) Int. Cl. G11B 5/706; C23C 14/32; B05D 5/12; B05D 1/02; B05D 1/18

(52) U.S. Cl. 428/833; 428/848.1; 427/127; 204/192.1; 427/256; 427/421.1; 427/430.1

(57) ABSTRACT

A recording medium for heat assisted magnetic recording includes a magnetic disc having a data zone portion and a non-data zone portion. A liquid lubricant is disposed on the non-data zone portion, and a solid lubricant disposed on the data zone portion. In one embodiment, the solid lubricant has a high thermal stability relative to the liquid lubricant.

### STATEMENT REGARDING FEDERALLY SPONSORED RESEARCH OR DEVELOPMENT

This invention was made with United States Government support under Agreement No. 70NANB1H3056 awarded by the National Institute of Standards and Technology (NIST). The United States Government has certain rights in the invention.

### CROSS-REFERENCE TO RELATED APPLICATION

None.

### FIELD OF THE INVENTION

The present invention relates to storage devices that utilize thin film magnetic media, and more particularly, to a method for lubricating a thin film magnetic media at a head-disc interface zone.

### BACKGROUND OF THE INVENTION

Most modern information storage systems depend on magnetic recording due to its reliability, low cost, and high storage capacity. The primary elements of a magnetic recording system are the recording medium, and the read/write head. Magnetic discs with magnetizable media are used for data storage in almost all computer systems. Current magnetic hard disc drives operate with the read-write heads only a few nanometers above the disc surface and at relatively high speeds, typically 15-40 meters per second. Depending on the diameter of the media, this value (the linear velocity at the outside diameter) can vary from 7 meters per second (m/s) on a one inch drive to 26 m/s (3.5 inch drive). Additionally, this value changes with the radius of the given media. Because the read-write heads can contact the disc surface during operation, a thin layer of lubricant (typically one to four nanometers thick) is coated on the disc surface to reduce wear and friction. The lubricant layer also protects the media from corrosion.

Thin film magnetic media are typically prepared with a protective overcoat formed from a thin layer of carbon, which protects the underlying magnetic layer against corrosion and wear. To improve the frictional properties of the head/disc interface (HDI), the carbon overcoat is coated with a lubricant layer. Conventionally, a thin layer of liquid lubricant is applied on the whole disk surface to reduce the friction and wear at the head-media interface. Such lubricants are either applied to the recording media by a vapor phase lubrication process or by a dip coating technique. When lubricants are applied using a dip coating technique, the lubricant is dissolved in a solvent at a selected concentration, and the media are dipped into the solution and withdrawn, or the solution is pumped over the media and then drained away. As the media are lifted or the solution drained, a meniscus of solution is dragged along the surface of the media. As the solvent evaporates, a thin film of the nonvolatile lubricant is left on the disc. The amount of lubricant left on the surface of the media may be controlled by varying the concentration of lubricant in the solution, and/or by varying either the rate at which the media is lifted or the rate at which the solution is drained.

It has been recognized that different portions of the disc surface may have different lubrication requirements. For example, wear due to larger numbers of contact start-stop cycles in areas where the read/write head contacts the recording media is a cause of drive failure, and the presence of lubricant in such areas can improve the durability and reliability of the disc drive. Consequently, it is important that lubricant applied to the disc remain distributed in such areas. To that end, a number of techniques have been developed to improve the durability and reliability of the disc media.

In one conventional technique, properties of the protective overcoat layer are adjusted in the areas susceptible to contact with the read/write head. Particularly, the overcoat is formed of varying areas of hardness (wherein the area of a landing or takeoff zone of the read/write head is harder than other areas of the storage media). In another conventional technique, the thickness of the overcoat layer is adjusted in selected areas. In another technique, a multi-phase carbon overcoat is employed with an amorphous carbon film layer deposited over the disc media and a second doped amorphous carbon film layer deposited in selected areas on top of the first layer.

Another conventional technique involves physical bonding of the lubricant to portions of the disc media. The physical bonding technique may involve chemical reactions or UV or other high energy irradiation.

Another conventional technique uses different lubricants on different portions of the disc surface. For example, zone-bonded lubrication for hard disc recording media (such as a low-bonded lubricant at the landing zone and a high-bonded lubricant at the data zone) is known. In one instance, a liquid lubricant (typically a polyfluoroether composition) is applied to the disc. The disc is then immersed in a degreaser, such as Vertrel XF® (2,3-dihydrodecafluoropentane), for period of time under ambient conditions. The disc is removed from the degreaser and the thickness of the lubricant is measured. In general, the ratio of the measured thickness of the lubricant to the initial thickness of the lubricant is referred to as a bonded ratio. In one instance, a low-bonded ratio refers to a lubricant having a bonded ratio of less than ½, and a high-bonded ratio refers to a lubricant with a bonded ratio of ½ or more.

Trends in the disc industry have raised new issues regarding the lubricants used with recording media. Heat-Assisted Magnetic Recording (HAMR), for example, has been recently proposed as a method for increasing the data density of the recording media to deliver 1 Tb/in² data density. HAMR requires the media to be heated by a laser, defined as light amplification by stimulated emission of radiation, during the recording process to a temperature of approximately its Curie temperature (the temperature at which ferromagnetic material becomes paramagnetic). For ferromagnetic materials, the Curie temperature is typically 350° C. or above. The laser heating process is expected to raise the temperature of the lubricant layer, which is likely either to evaporate or to decompose liquid lubricants. The evaporation and/or the decomposition of the lubricant can cause a general failure of the head-disc interface (HDI).

Therefore, for heat-assisted applications, a new design is needed to improve the thermal stability of the HDI. Embodiments of the present invention provide solutions to these and other problems, and offer other advantages over the prior art.

### SUMMARY OF THE INVENTION

A recording medium for heat assisted magnetic recording includes a magnetic disc having a data zone portion and a non-data zone portion. A liquid lubricant is disposed on the non-data zone portion, and a solid lubricant disposed on the data zone portion. In one embodiment, the solid lubricant has a high thermal stability relative to the liquid lubricant.

In another embodiment, a method for lubricating a storage medium is described. A non-data zone of the storage medium is coated with a liquid lubricant. A solid lubricant is deposited on a data zone of the storage medium.

A magnetic recording medium includes a data zone and a non-data zone. A solid lubrication layer is disposed on the data zone. A liquid lubrication layer is disposed on the non-data zone.

Other features and benefits that characterize embodiments of the present invention will be apparent upon reading the following detailed description and review of the associated drawings.

### BRIEF DESCRIPTION OF THE DRAWINGS

FIG. 1 is an isometric view of a disc drive.

FIG. 2A is a top view of a disc media for use in high temperature applications having a loading zone adjacent to the outer circumferential edge of the disc for use in a dynamic load/unload disc drive system according to an embodiment of the present invention.

FIGS. 2B and 2C are cross-sectional views of disc media taken along line 2B-2B in FIG. 2A.

FIG. 3A is a top view of a mask for solid lubricant deposition for a disc media having a loading zone adjacent the outer circumferential edge of the disc for use in a dynamic load/unload disc drive system according to an embodiment of the present invention.

FIG. 3B is schematic representation of a solid lubricant deposition process using the mask of FIG. 3A.

FIG. 4 is a simplified flow diagram of a process of lubricating a disc media for use in high temperature applications having a loading zone adjacent to the outer circumferential edge of the disc for use in a dynamic load/unload disc drive system according to an embodiment of the present invention.

FIG. 5 is a simplified schematic representation of a rotational lubrication process according to an embodiment of the present invention.

FIG. 6A is a top view of a disc media for use in high temperature applications in conjunction with a contact start/stop storage system according to an embodiment of the present invention.

FIG. 6B is a cross-sectional view of the disc media taken along line 6B-6B in FIG. 6A.

FIG. 7A is a top view of a mask for solid lubricant deposition for a disc media having a landing zone adjacent to the inside edge of the disc for use in a contact start/stop disc drive system according to an embodiment of the present invention.

FIG. 7B is schematic representation of a solid lubricant deposition process using the mask of FIG. 7A.

FIG. 8 is a simplified schematic representation of a dip-coating process followed by a rotational de-lubrication process according to an embodiment of the present invention.

### DETAILED DESCRIPTION OF ILLUSTRATIVE EMBODIMENTS

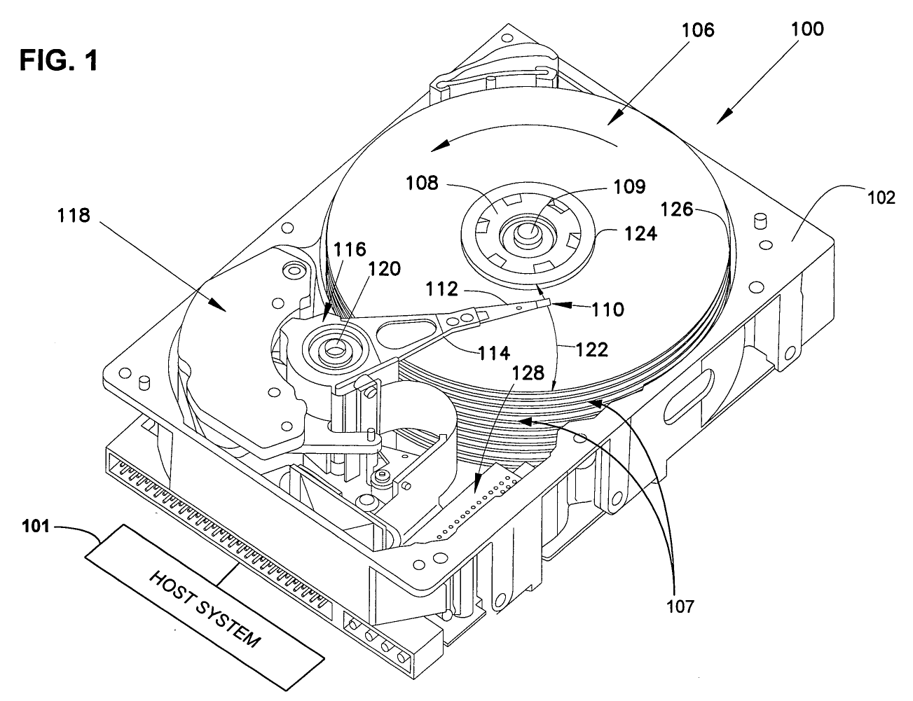

FIG. 1 is an isometric view of a disc drive 100 in which embodiments of the present invention are useful. Disc drive 100 includes a housing with a base 102 and a top cover (not shown). Disc drive 100 further includes a disc pack 106, which is mounted on a spindle motor (not shown) by a disc clamp 108. Disc pack 106 includes a plurality of individual discs, which are mounted for co-rotation about central axis 109. Each disc surface has an associated disc head slider 110 which is mounted to disc drive 100 for communication with the disc surface.

In the example shown in FIG. 1, sliders 110 are supported by suspensions 112 which are in turn attached to track accessing arms 114 of an actuator 116. The actuator shown in FIG. 1 is of the type known as a rotary moving coil actuator and includes a voice coil motor (VCM), shown generally at 118. Voice coil motor 118 rotates actuator 116 with its attached heads 110 about a pivot shaft 120 to position heads 110 over a desired data track along an accurate path 122 between a disc inner diameter 124 and a disc outer diameter 126. Voice coil motor 118 is driven by servo electronics 128 based on signals collected by heads 110 and a host computer (not shown).

The present invention introduces a system and method for producing magnetic discs, which can be utilized with heat assisted magnetic recording (HAMR) devices, in addition to being useful in standard magnetic recording devices. Additionally, the technique of the present invention may be applicable to any media for which lubricants having different properties are required for different areas on the media. More particularly, the present invention introduces a method of producing discs which can be utilized in heat assisted recording applications without concern that lubricant loss will occur.

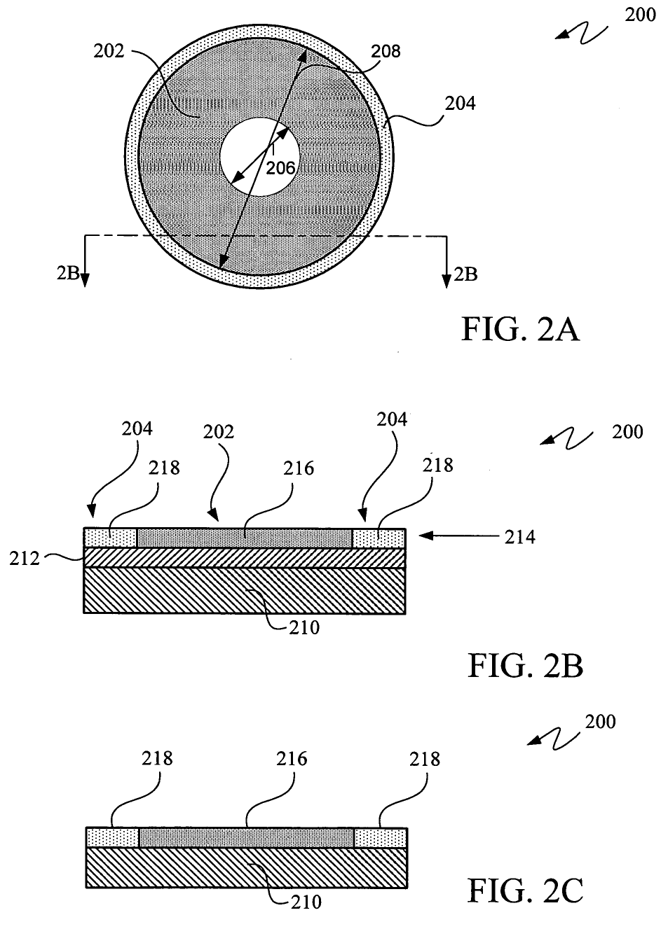

FIG. 2 illustrates a simplified view of the surface of the recording media for use with dynamic load/unload system according to an embodiment of the present invention. In a dynamic load/unload disc drive, a load/unload ramp is utilized to transfer the read/write transducer between the disc and a “parked” position adjacent to the disc. The load/unload ramp is typically stationary and located at a peripheral portion of the disc.

The disc media 200 is divided into a solid lubricated data zone 202 and a liquid lubricated loading zone 204 (a circumferential zone along an outside periphery of the disc media 200). The data zone 202 corresponds to the area of the disc media 200 where data is stored. The loading zone 204 is the area of the disc media where the read/write transducer is dynamically loaded over the disc media 200. Typically, the loading zone is a couple of millimeters wide. As used herein, the loading zone 204 refers to an area on the surface of a disc media, which is conditioned for possible contact between a read/write transducer (a read/write head) and the disc. In a preferred embodiment, the loading zone 204 is a track extending circumferentially about the surface of the disc and having substantially the same width as a slider of the read/write transducer.

The data zone 202 has an inside diameter 206 and an outside diameter 208, and is coated with a solid lubricant having a low surface tension, such as Polytetrafluoroethylene (PTFE) and other fluoro-polymers. The loading zone 204 extends from the outside diameter 208 of the data zone 202 to the outer edge of the disc media 200. The loading zone 204 defines a radial band that encircles the data zone 202 and that has a width (W′). In one embodiment, the width (W) is approximately twice a width of the slider of the read/write head. In a preferred embodiment, the width (W) is approximately equal to the width of the slider.

The present invention presents a technique for improving the thermal stability of the HDI for use with high temperature applications, such as heat assisted magnetic recording (HAMR). Thermal stability refers to the ability of the lubricant to resist vaporization, intrinsic and oxidative decomposition under high temperature operating conditions. In HAMR systems, a laser is utilized to heat portions of the data zone 202 as data is written to the disc media 200. Since the laser is intended to raise the temperature of the surface of the disc media 200 to approximately a Curie temperature in order to facilitate magnetic recording, a solid lubricant (such as sputtered PTFE) is deposited on the data zone 202 of the disc media 200. The solid lubricant does not evaporate or otherwise break down at the Curie temperature. The low surface tension of the solid lubricant provides corrosion protection, prevents flow of the liquid lubricant from the loading zone 204 to the data zone 202, and allows the disc media 200 to be used in high temperature applications (such as HAMR).

In general, the surface tension of, for example, polytetrafluoroethylene (PTFE) is lower than that of the carbon overcoat layer, but is relatively comparable to the surface tension of, for example, a perflouropolyether (PFPE) liquid lubricant. In the prior art, liquid lubricant tends to migrate toward the unlubricated zone because the surface tension of the carbon overcoat layer is higher than the PFPE liquid lubricant. By placing a solid lubricant in the previously uncoated zone, thermodynamically, the driving force for liquid lubricant migration becomes much lower since the surface tensions of the solid and liquid lubricants are relatively comparable.

Moreover, since the read/write head is loaded to the disc media 200 only in the loading zone 204 and since the laser is not turned on while the head is in the loading zone 204, lubricant used in the loading zone 204 does not need to share the temperature-related properties of the solid lubricant. Since only the data zone 202 is heated, the lubricants coated on the loading zone 204 do not experience very high temperature, and thermal stability of the liquid lubricant is not a concern. More specifically, liquid lubricants, which are desirable in the loading zone 204 because they reduce frictional wear, may be used in the loading zone 204 without concern for laser-induced breakdown or evaporation, and without concern for the migration of the liquid lubricant into the data zone 202. Since the head is loaded to the disc media 200 only on the lubricated loading zone 204, the friction and wear are still effectively reduced. Thus, the present invention provides high temperature stability, corrosion protection and fixed lubricant distribution at the same time.

FIG. 2B is a cross-sectional view of the disc media 200 taken along line 2B-2B in FIG. 2A. The disc media 200 has a magnetic layer 210 with a protective overcoat 212, such as a carbon overcoat. Lubricant layer 214 is deposited on the overcoat 212. The lubricant layer 214 is formed from a solid lubricant 216 disposed on the data zone 202 and a liquid lubricant 218 disposed on the loading zone 204.

By providing a different lubricant in the loading zone 204 as compared to the data zone 202, the present invention takes advantage of the selective use of the laser to heat the disc media 200. Since only the data zone 202 of the disc 200 is heated by the laser, only the data zone 202 needs to be coated with material capable of withstanding the heat. The loading zone 204 can make use of other lubricants that may be more advantageous with respect to friction between the read/write head and the disc media 200. It should be appreciated that the low surface tension of solid lubricant 216 in data zone 202 provides corrosion protection for the disc media 200. The low surface tension of the solid lubricant 216 also prevents the liquid lubricant 218 from flowing from the loading zone 204 to the data zone 202. Finally, by utilizing the liquid lubricant only in the landing zone, the disc media 200 of the present invention may be utilized with heat assistant magnetic recording (HAMR) devices. As previously mentioned, since only the data zone will be heated, the liquid lubricant 218 coated on the loading zone 204 does not experience very high temperatures, and high thermal stability of the liquid lubricant 218 is not required. Only the solid lubricant is required to withstand the extreme temperatures required by the HAMR recording process.

FIG. 2C is a cross-sectional view of the disc media 200 taken along line 2B-2B in FIG. 2A according to an alternative embodiment of the present invention. The disc media 200 has a magnetic layer 210 with a lubricant layer 214 deposited directly on the magnetic layer 210. The lubricant layer 214 is formed from a solid lubricant 216 disposed on the data zone 202 and a liquid lubricant 218 disposed on the loading zone 204.

This embodiment of the disc media 200 eliminates the overcoat layer (element 212 in FIG. 2B), thereby eliminating a processing step. In this embodiment, the solid lubricant 216 provides the corrosion resistance formerly provided by the overcoat layer.

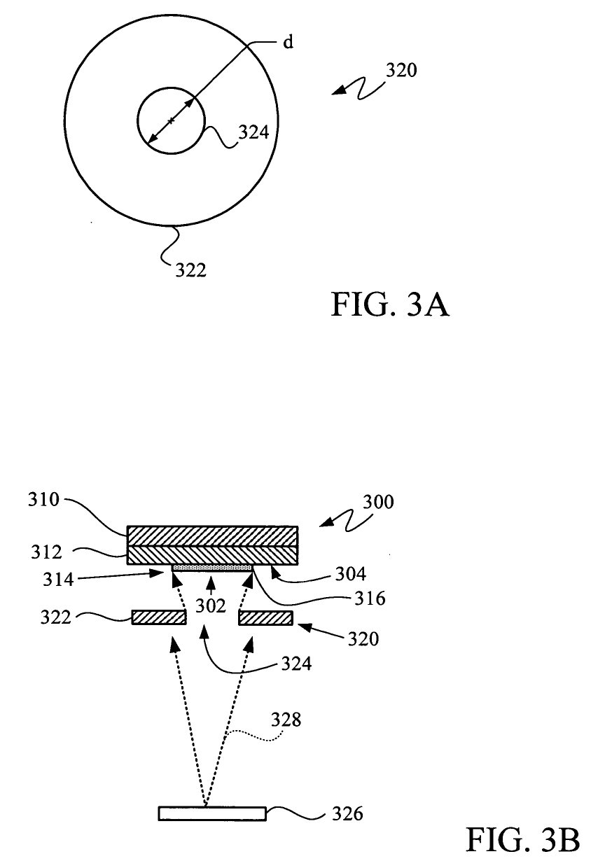

FIG. 3A illustrates a mask 320 for use sputter depositing the solid lubricant onto the disc substrate according to one embodiment of the present invention. The mask 320 is basically a shutter plate 322 with an opening 324 of appropriate diameter (d).

FIG. 3B illustrates a schematic view of the solid lubricant deposition process according to an embodiment of the present invention. In order to deposit the solid lubricant only in the data zone of the disc media, a suitable mask structure 320 is disposed between a sputtering gun and the substrate comprised of a magnetic layer 310 and an overcoat layer 312. Solid lubricant material 328 is sputtered from a PTFE target 326, through the opening 324 in the shutter plate 322 and onto the overcoat layer 312 to form a solid lubricant-coated region 316, corresponding to the data zone 302 of the disc media 300. Generally, the mask 320 is arranged relative to the substrate such that the sputtered PTFE-coated region 316 corresponds to the data zone 302 of the disc media.

Since HDI integrity must be preserved, the mask 320 does not contact the disc surface. Therefore, specific design of the mask 320 depends on the distance between the target and the substrate and on the angle of deposition of sputtered material to produce the desired “shadowing” effect. Thus, only sputtered material 328 able to pass through the mask 320 is deposited on the overcoat 312 while the loading zone 304 (the outside diameter circumferential band where the read/write head is dynamically loaded to the disc media) is not coated by the solid lube material 328.

In general, the solid lubricants can be any solid films with low surface tension, high thermal stability, and excellent tribological properties. The solid lubricant film can be deposited on the disc surface by various vacuum deposition techniques, including sputter deposition, plasma-enhanced chemical vapor deposition, ion beam deposition, and the like. One possible example is sputtered polytetrafluoroethylene (PTFE) film.

A variety of liquid lubricants can be applied on the disc surface, including Fomblin® Z and Y lubricants from Ausimont Inc., Krytox® lubricants from Du Pont, Demnum® lubricants from Daikin America, Inc., and A20H lubricants from Matsumura Oil Research Corp (Moresco). The molecular weight of these liquid lubricants could range from a few hundred amu to ten thousand amu and above.

In one embodiment, the lubricant is deposited on the disc in a deposition chamber held at sufficiently low pressure so as to provide a line of sight deposition of the lubricant vapor onto the disc surface. In this case, a sufficiently low pressure means that the mean free path of the lubricant vapor is greater than a distance of the disc from the vapor source. One example of the line of sight deposition of lubricant vapor includes the vapor deposition device described in U.S. Pat. No. 6,099,896, which is incorporated herein in its entirety. The vapor deposition device directs a lubricant vapor through one or more orifices to produce a virtual beam of liquid lubricant, which can be used to coat recording media in one or more select locations. The device can also directly apply the lubricant vapor without the orifices.

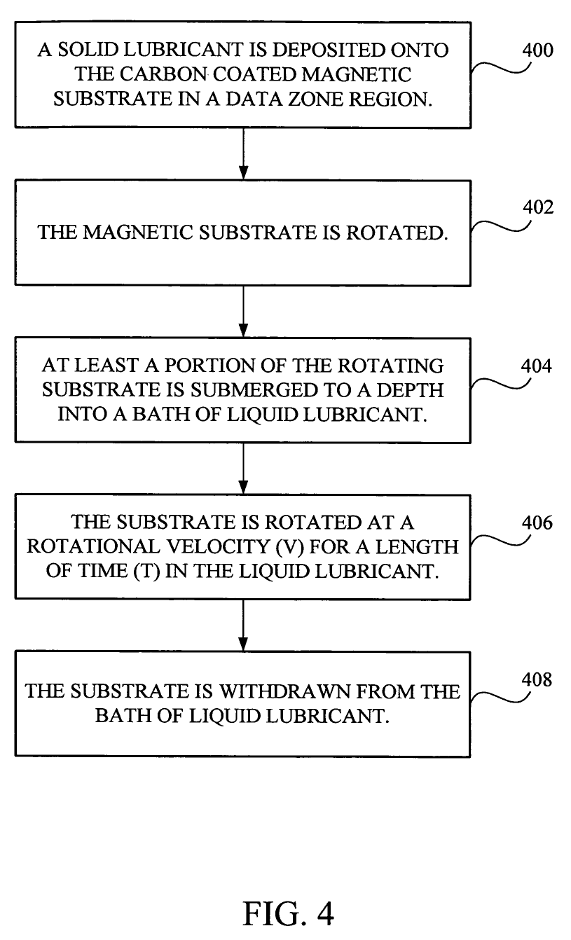

FIG. 4 is a simplified flow diagram of a process for producing a lubricated disc media according to an embodiment of the present invention. A solid lubricant is deposited onto the carbon coated magnetic substrate in a data zone region (block 400). The magnetic substrate is rotated (block 402), and a portion of the rotating substrate is submerged to a predetermined depth into a bath of liquid lubricant solution (block 404). The substrate is maintained at a predetermined rotational velocity (v) and for a predetermined length of time or “dwell time” (t) in the lubricant solution (block 406). The substrate is withdrawn from the solution while still rotating (block 408).

In general, the depth that the rotating disc is submerged into the lubricating liquid may be referred to as a “dip depth”. The area of the lubricated zone is determined, in part, by controlling the dip depth. In general, the thickness of the lubricant layer may be controlled by adjusting the rotational velocity, by adjusting the dwell time of the disc in the solution, and/or by adjusting the concentration of the lubricant solution.

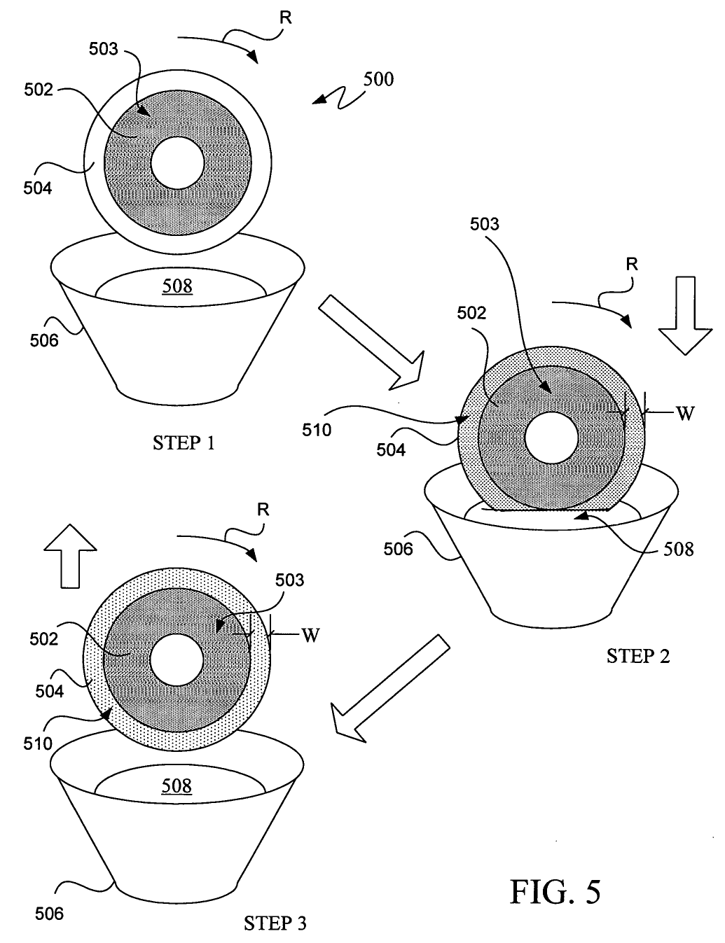

FIG. 5 illustrates a schematic view of a new lubrication process for applying a lubricating liquid only on the loading zone (outer diameter circumferential band corresponding to an area on the disc where the read/write head is dynamically loaded to the disc media) of the disc media according to an embodiment of the present invention. The lubrication process may be referred to as “rotational lubrication”. The disc media 500 is partitioned into a data zone 502 and a loading zone 504. The data zone 502 has already been coated with a solid lubricant 503 via a deposition process. The disc media 500 is rotated (in a direction indication by arrow R) adjacent to container 506 that is filled with a liquid lubricant solution 508. (step 1). It should be understood by a worker skilled in the art that the direction of rotation indicated by arrow R is provided as an example only. The disc media 500 may be rotated in a clockwise or counterclockwise direction.

The rotating disc media 500 is lowered into the liquid lubricant solution 508 to a desired depth (W), corresponding to the width of the loading zone 504 (step 2). The rotational velocity of the disc media 500 may be held constant or varied according to the desired thickness of the liquid lubricant. During this step, the loading zone 504 is coated with a liquid lubricant layer 510 from the lubricant solution 508.

The rotating disc media 500 is raised from the liquid lubricant solution 508 while the disc media 500 is still rotating (step 3). The low surface tension of the solid lubricant 503 in the data zone 502 prevents the liquid lubricant layer 510 from flowing into the data zone 502. Moreover, since the disc media 500 is preferably dipped to a depth equal to the width (W) of the loading zone 504, the data zone 502 of the disc media 500 is not coated by the liquid lubricant 508.

As previously mentioned, the area of the lubricated zone is controlled by changing “dip depth”. The thickness of lubricant layer is controlled by adjusting rotational velocity, the dwell time in the lubricant solution, and the concentration of the lubricant solution.

In an alternative embodiment, the liquid lubricant layer 510 is deposited on the loading zone 504 using a vaporized liquid lubricant 508, as taught by U.S. Pat. No. 6,355,300 issued to Michael Stirniman et al. and entitled “DISC LUBRICATION FOR THE LOAD/UNLOAD DISC INTERFACE”, which is incorporated herein by reference in its entirety. In general, by carefully positioning the deposition nozzle while the disc is rotating during the deposition, a liquid lubricant film can be deposited on the loading zone 504 only. The vapor lubrication process can be conducted in a deposition chamber with controlled pressure. Thus, the disc can be transferred to this deposition chamber after solid lubricant deposition without breaking the vacuum, thereby improving the bonded ratio of liquid lubricants and further preventing liquid lubricant migration. In this instance, the liquid lubricant is applied to the surface of the disc with fewer impurities (such as air, hydrocarbon vapor, and the like), thereby creating a better surface.

In general, when comparing thermal stability of the solid lubricant versus thermal stability of the liquid lubricant, the solid lubricant has a higher thermal stability. Generally, thermal stability refers to the resistance of a material to drastic changes in temperature. As used herein, the term “thermal stability” refers to the ability of the lubricant to resist vaporization, intrinsic and oxidative decomposition or to maintain its physical properties under high temperature operating conditions. Thus, the solid lubricant is more resistant to decomposition and vaporization at high temperatures than the liquid lubricant. In one embodiment, the lubricant solution is made with Ztetraol lubricant from Ausimont. In another embodiment, the lubricant solution is made from a fluorocarbon solvent, such as Vertrel® XF solvent from E. I. du Pont de Nemours and Company or PF-5060DL and HFE 7200 from 3M Corporation of Minnesota. The concentration of the solution is g/mL. A disc is lubricated by the rotation lubrication technique of the present invention, so that only the non-data zone is coated with the liquid lubricant. The rotation speed is approximately one to ten revolutions per minute (RPM) in the lubrication process.

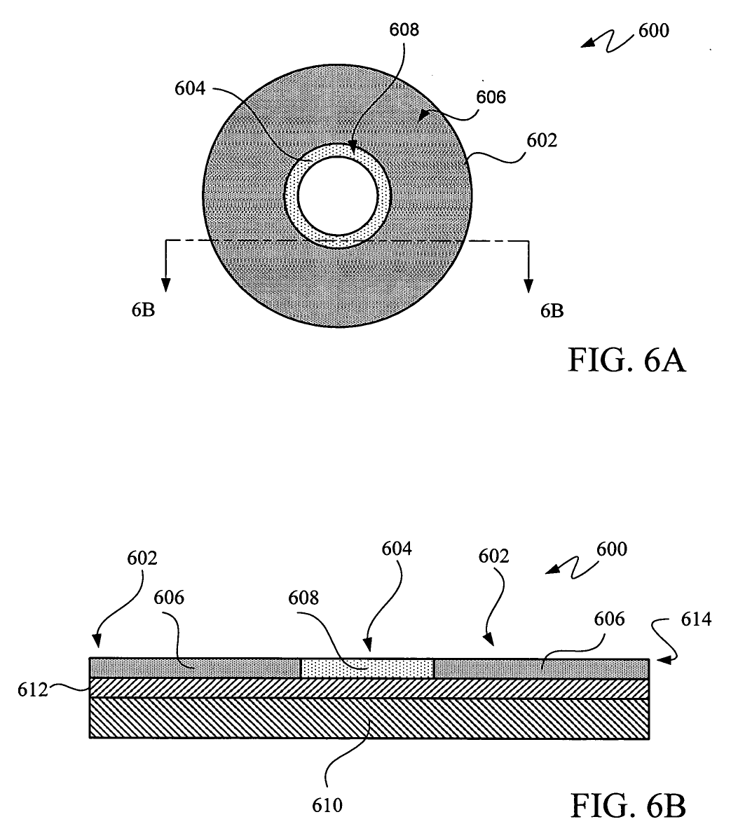

FIGS. 6A and 6B illustrate a disc media 600 for use in high temperature applications in conjunction with a contact start/stop (CSS) storage system according to an embodiment of the present invention. The disc media 600 is divided into a data zone 602 and a takeoff and landing zone 604 (an inner diameter zone or circumferential band extending around an inside diameter of the disc media 600). In a CSS system, the read/write transducer takes off and lands on the takeoff and landing zone 604 (hereinafter referred to as a “landing zone 604”, which is adjacent to the inner periphery of the data zone 602). The landing zone 604 is typically roughened to minimize the stiction of the read/write transducer against the surface of the disc media 600.

A solid lubricant 606 with low surface tension (such as sputtered PTFE, and the like) is deposited on the surface of the disc media 600 in the data zone 602. A liquid lubricant 608 is deposited on the surface of the disc media 600 in the landing zone 604.

In FIG. 6B, the disc media 600 is shown in cross-section taken along line 6B-6B in FIG. 6A. The disc media 600 has a magnetic layer 610 with an overcoat 612. Lubricant layer 614 is deposited on the overcoat 612. The lubricant layer 614 is formed from a solid lubricant 606 deposited in the data zone 602 and a liquid lubricant 608 disposed on the landing zone 604.

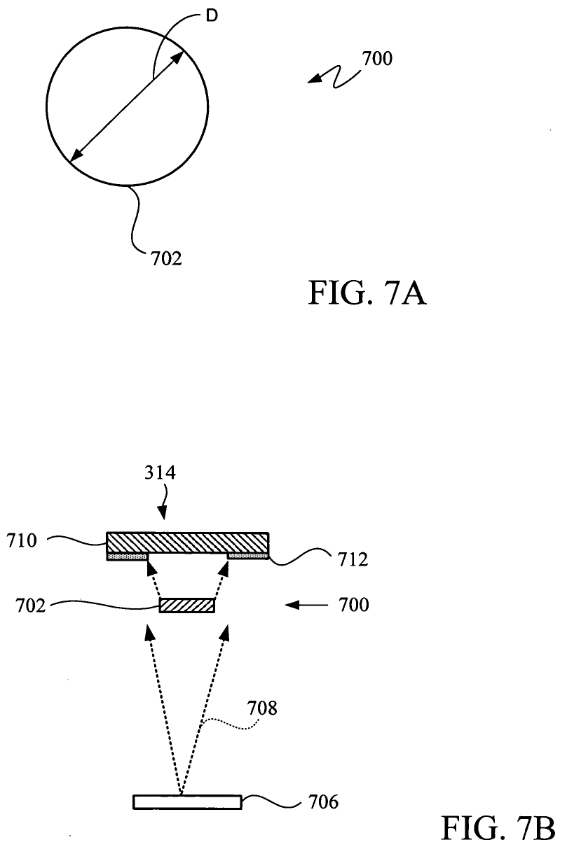

In general, the solid lubricant can be sputter deposited from, for example, a polytetrafluoroethylene target. FIG. 7A illustrates a suitable mask structure 700 for depositing the solid lubricant in the data zone. The mask structure 700 is basically a shutter plate 702 with an appropriate diameter (D).

One technique for depositing the solid lubricant is shown in FIG. 7B. The mask structure 700 is disposed between the sputtering gun and the substrate. The solid lubricant material 708 is sputtered from a PTFE target 706 onto the disc substrate 710. A solid lubricant-coated region 712 is formed on the substrate 710. Generally, the mask 700 is arranged relative to the substrate such that the sputtered PTFE-coated region 712 corresponds to the data zone of the disc media. Since the head/disc interface must be preserved, the shutter plate 702 does not contact the surface of the substrate 710.

The specific design of the mask depends on the target-to-substrate distance and the angle of deposition of the sputtered material to produce the desired shadowing effect. Only the data zone is coated with the solid lubricant 712, while the landing zone is shielded by the mask 700. After solid lubricant is deposited on the data zone, a liquid lubricant may be applied to the landing zone by, for example, a vapor lube process as described above.

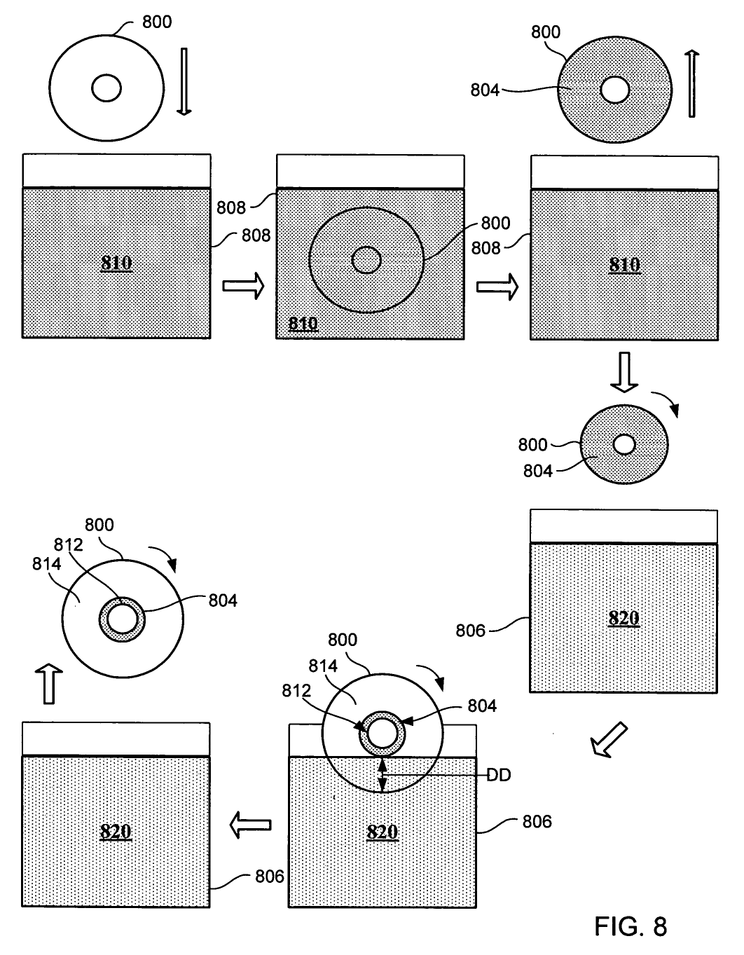

FIG. 8 illustrates a simplified schematic diagram of an alternative approach to achieving a desired lubricant distribution on the disc media 800 for use in a CSS storage system. This alternative approach is a two-step process including a dip-lubrication step and “rotational de-lubrication” step.

A disc media 800 is provided. Conceptually, the disc media 800 is divided into a data zone and a non-data zone. In this instance, FIG. 8 illustrates a process whereby the non-data zone is created on an inner periphery of the disc media 800. The disc media 800 is positioned adjacent to a container 808 containing a solution of liquid lubricant 810. Generally, the disc media 800 is submerged in the liquid lubricant 810 to coat the whole disc media 800 with a liquid lubricant without any functional end-groups. The disc media 800 is then removed from the liquid lubricant 810, leaving a disc media 800 with a liquid lubricant coated layer 804, coating the entire surface of the disc media 800. Inclusively, the process to this point may be referred to as the dip-coating step. The de-lubrication step refers to a process of selectively removing the liquid lubricant coated layer 804 from a data zone area of the disc surface.

It should be understood that to coat the non-data zone of the disc media (sometimes referred to as a loading zone or landing zone), the disc media 800 is at least partially submerged in the liquid lubricant 810 within the container 808, such that the non-data zone is submerged in the liquid lubricant 810. In the embodiment shown, the disc media 800 is completely submerged in the solution of liquid lubricant 810, a process which can be referred to as “dip-coating”. However, in an alternative embodiment, the disc media 800 could be submerged only to a depth sufficient to cover the non-data zone of the disc media 800 while rotating the disc media 800. In another embodiment, one half of the diameter of the disc media 800 could be submerged in the liquid lubricant 810 while rotating the disc media 800, thereby coating an entire surface of the disc media without total submersion. In a preferred embodiment, the full disc surface is coated with a liquid lubricant 810 without any functional end-groups by a dip-pull process known in the hard disc industry.

Referring now to the delubrication step, to eliminate liquid lubricant 810 on a data zone area of the disc media, the disc media 800 is rotated, such as indicated by the curved arrow R, and is positioned adjacent to a container 806 containing a solvent 820. While rotating the coated disc media 800 at a certain rotational velocity, the disc media 800 with the coated layer 804 is lowered into the solvent 820 in container 806 to a desired depth (DD). The desired depth (DD) preferably corresponds to a radial width of a data zone area 814 of the disc media 800. Thus, the liquid lubricant coating layer 804 is removed from the data zone 814 and is left on the non-data zone area 812 of the disc media 800. The solvent 820 may be any solvent capable of removing the liquid lubricant 810 from the disc media 800. One such solvent, for example, may be Vertrel XF.

After continuously rotating the disc media 800 in the solvent 820 for a desired period of time, the disc media 800 is removed from the solvent 820 while still rotating. Since only the data zone 814 is in contact with the solvent 820, the liquid lubricant coating 804 remains on the surface of the disc media 800 in a non-data zone area 814. Thus, via the dip-coating and rotational de-lubrication steps, the disc media 800 is effectively partitioned into a data zone 814 and a non-data zone 812 corresponding to a landing zone of the storage device.

In one embodiment, the solid lubricant is deposited on the data zone 802 prior to the dip-coating process. The solvent is selected to react with the liquid lubricant 810 while leaving the solid lubricant behind. Alternatively, the liquid lubricant 810 is deposited and selectively removed as described above, then a solid lubricant is sputtered onto the data zone area 814 with an appropriate mask design, such as indicated by reference numeral 700 in FIGS. 7A and 7B above.

In an alternative embodiment of the present invention, no mask is required to achieve the desired lubricant distribution. Instead, the solid lubricant may be sputter-deposited onto the full disc surface, and then the solid lubricant may be removed from a portion of the disc surface using irradiation, such as laser or electron-beam (e-beam) irradiation, etching or ionization processes. For example, a mask may be used for an etching process, but the mask could be eliminated from the deposition perspective. Afterwards, the liquid lubricant can be applied on the appropriate region of the disc surface.

In addition to the above techniques, the disc can be coated with a solid lubricant on the desired region, either on the data zone or the whole disc. Then, the disc may be coated with a liquid lubricant on the desired region. In still another embodiment, the solid lubricant may be deposited on the appropriate region, then the whole disc may be submerged in a liquid lubricant solution. In this embodiment, the lubricant may be selected from lubricants that do not bond with the deposited solid lubricant such that when the disc is removed from the bath, the liquid lubricant simply flows off of the solid lubricant in the data zone.

While the present invention has been described with respect to a take off and landing zone or “landing zone” in a contact start/stop storage system and with respect to a dynamic loading zone in a dynamic or ramp load storage system, it should be understood that both the landing zone and the loading zone may be generically described by the term “non-data zone”. Specifically, in either case, data is stored in the data zone while the non-data zone is not used for data storage.

It is to be understood that even though numerous characteristics and advantages of various embodiments of the invention have been set forth in the foregoing description, together with details of the structure and function of various embodiments of the invention, this disclosure is illustrative only, and changes may be made in detail, especially in matters of structure and arrangement of parts within the principles of the present invention to the full extent indicated by the broad general meaning of the terms in which the appended claims are expressed. For example, the particular order of steps and the locations of and types of lubricants on the disc media may vary depending on the particular type of storage media system (contact start/stop or dynamic load/unload, and the like) while maintaining substantially the same functionality without departing from the scope and spirit of the present invention. In addition, although the preferred embodiment described herein is directed to a zone-lubricated magnetic recording system for use with heat assisted magnetic recording systems, it will be appreciated by those skilled in the art that the teachings of the present invention can be applied to, but not restricted to, any data storage system, such as magnetic and optical recording systems, wherein the read/write head lands on and takes off from the storage media, without departing from the scope and spirit of the present invention.

What is claimed is:

1. A recording medium for heat assisted magnetic recording comprising:
a magnetic disc comprised of a data zone portion and a non-data zone portion;
a liquid lubricant disposed on the non-data zone portion; and
a solid lubricant disposed on the data zone portion.

2. The recording medium of claim 1 wherein the data zone portion comprises:
a data storage area of the magnetic disc.

3. The recording medium of claim 1 wherein the non-data zone portion comprises:
an area of the disc media over which a read/write transducer is dynamically loaded.

4. The recording medium of claim 1 wherein the solid lubricant comprises:
a lubricant having a high thermal stability relative to the liquid lubricant.

5. The recording medium of claim 1 wherein the recording medium is disposed within a heat-assisted magnetic disc drive assembly.

6. The recording medium of claim 1 wherein the solid lubricant comprises sputtered Polytetrafluoroethylene.

7. A magnetic recording medium comprising:
a data zone;
a solid lubrication layer disposed on the data zone;
a non-data zone; and
a liquid lubrication layer disposed on the non-data zone.

8. The magnetic recording medium of claim 7 wherein the data zone lubrication layer comprises a layer formed from a solid lubricant.

9. The magnetic recording medium of claim 8 wherein the solid lubricant comprises sputtered polytetrafluoroethylene.

10. The magnetic recording medium of claim 8 wherein the data zone lubrication layer has a higher thermal stability than the liquid lubrication layer.

11. The magnetic recording medium of claim 7 wherein the data zone and the non-data zone comprise concentric bands of the magnetic recording medium.

12. The magnetic recording medium of claim 7 wherein the data zone extends from a circumferential edge of the magnetic recording medium to a circumferential edge of the non-data zone of the storage medium.

13. A method for lubricating a storage medium comprising:
depositing a solid lubricant having a high thermal stability on a data zone of the storage medium; and
depositing a liquid lubricant on a non-data zone of the storage medium.

14. The method of claim 13 wherein the solid lubricant has a low surface tension relative to a media overcoat layer of the storage medium.

15. The method of claim 14 wherein the solid lubricant has a similar surface tension relative to the liquid lubricant.

16. The method of claim 13 wherein the solid lubricant comprises sputtered Polytetrafluoroethylene.

17. The method of claim 13 wherein the liquid lubricant is selected from a group consisting of Fomblin® Z and Y lubricants, Krytox® lubricants, Demnum® lubricants and Moresco A20H lubricants.

18. The method of claim 13 wherein a molecular weight of the liquid lubricant is greater than or equal to 200 amu.

19. The method of claim 13 wherein the step of depositing the solid lubricant comprises:
positioning a mask between a solid lubricant source and a storage medium; and
directing a spray of the solid lubricant onto a surface of the storage medium that is not shielded by the mask.

20. The method of claim 13 wherein the step of depositing the liquid lubricant comprises:
coating the storage medium in a solution of the liquid lubricant;
immersing at least partially the storage medium in a solvent solution to a depth corresponding to a radial thickness of the data zone; and
rotating the storage medium during immersion.

21. The method of claim 20 wherein the solvent solution comprises a lubricantsuch as Fomblin Z and Y lubricants, Krytox lubricants, Demnum lubricants, and Moresco A20H lubricants, and a fluorocarbon solvent.

22. The method of claim 13 wherein the solid lubricant and the liquid lubricant are deposited directly on a magnetic layer of the storage medium.
